(19) United States
(12) Patent Application Publication
(10) Pub. No.: US 2026/0271459 A1
(43) Pub. Date: Sep. 10, 2026

(54) LIGHT EMITTING DIODE PACKAGE STRUCTURE AND MANUFACTURING METHOD THEREOF

(71) Applicant: INGENTEC CORPORATION, Miaoli County (TW)

(72) Inventors: Chia-Pin WANG, Miaoli County (TW); Hsiao-Lu CHEN, Miaoli County (TW); Yi-Chuan HUANG, Miaoli County (TW); Ai-Sen LIU, Miaoli County (TW)

(21) Appl. No.: 19/369,314

(22) Filed: Oct. 26, 2025

(30) Foreign Application Priority Data
Mar. 5, 2025 (TW) 114108021

(51) Int. Cl. H10H 29/80; H10H 29/01; H10H 29/85

(52) U.S. Cl. CPC H10H 29/842; H10H 29/034; H10H 29/0364; H10H 29/8508; H10H 29/857

(57) ABSTRACT

A light emitting diode package structure includes a conductive substrate, a first insulating layer, a plurality of light emitting diode elements, a first conductive layer, a second insulating layer and a second conductive layer. The first insulating layer is disposed on a surface of the conductive substrate, and the first insulating layer has a plurality of first through holes. The light emitting diode elements are embedded in the first insulating layer. The first conductive layer is connected between the first insulating layer and the connecting surface of each of the light emitting diode elements. The second insulating layer is connected to the first conductive layer, and the second insulating layer has a plurality of second through holes. The second conductive layer is disposed in the second through holes and connected to the first conductive layer. The conductive substrate is a transparent conductive substrate.

### RELATED APPLICATIONS

This application claims priority to Taiwan Application Serial Number 114108021, filed Mar. 05, 2025, which is herein incorporated by reference.

### BACKGROUND

### Technical Field

The present disclosure relates to a light emitting diode package structure. More particularly, the present disclosure relates to a light emitting diode package structure and manufacturing method thereof, which can improve the manufacturing convenience and transparency.

### Description of Related Art

In the conventional light emitting diode packaging process, a plurality of light emitting diode components are usually fixed on a substrate, and then connected to the light emitting diode components by wires to form a circuit for current and signal transmission, and finally packaged with colloid. However, the conventional light emitting diode packaging process involves multiple procedures, so the production efficiency and the convenience in structural adjustment are reduced. Moreover, because of configuration of light emitting diode components and other structures, the packaged product difficultly maintain high transparency during not emitting light.

### SUMMARY

According to one aspect of the present disclosure, a light emitting diode package structure includes a conductive substrate, a first insulating layer, a plurality of light emitting diode elements, a first conductive layer, a second insulating layer and a second conductive layer. The first insulating layer is disposed on a surface of the conductive substrate, and the first insulating layer has a plurality of first through holes. The light emitting diode elements are embedded in the first insulating layer, a light emitting surface of each of the light emitting diode elements is connected to the conductive substrate, and a connecting surface of each of the light emitting diode elements is exposed to each of the first through holes which is corresponding to each of the light emitting diode elements. The first conductive layer is connected between the first insulating layer and the connecting surface of each of the light emitting diode elements, and the first insulating layer is located between the first conductive layer and the conductive substrate. The second insulating layer is connected to the first conductive layer, the first conductive layer is located between the first insulating layer and the second insulating layer, the second insulating layer has a plurality of second through holes, and a part of the first conductive layer is exposed to the second through holes. The second conductive layer is disposed in the second through holes and connected to the first conductive layer. The conductive substrate is a transparent conductive substrate.

According to another aspect of the present disclosure, a manufacturing method of a light emitting diode package structure includes following steps. A plurality of light emitting diode elements is disposed on a surface of a conductive substrate, and a light emitting surface of each of the light emitting diode elements faces toward the conductive substrate. A first insulating layer is formed on the surface of the conductive substrate, and the light emitting diode elements are embedded in the first insulating layer. A plurality of first through holes is formed at the first insulating layer, and a connecting surface of each of the light emitting diode elements is exposed to each of the first through holes which is corresponding to each of the light emitting diode elements. A first conductive layer is formed, the first conductive layer is connected to the first insulating layer and the connecting surface of each of the light emitting diode elements, and the first insulating layer is located between the first conductive layer and the conductive substrate. A second insulating layer is formed, the second insulating layer is connected to the first conductive layer, and the first conductive layer is located between the first insulating layer and second insulating layer. A plurality of second through holes is formed at the second insulating layer, and a part of the first conductive layer is exposed to the second through holes. A second conductive layer is disposed in the second through holes, and the second conductive layer is connected to the first conductive layer so as to obtain the light emitting diode package structure. The conductive substrate is a transparent conductive substrate.

### BRIEF DESCRIPTION OF THE DRAWINGS

The present disclosure can be more fully understood by reading the following detailed description of the embodiment, with reference made to the accompanying drawings as follows:

FIG. 1 is a cross-sectional schematic view of a light emitting diode package structure according to one embodiment of the present disclosure.

FIG. 2 is a bottom schematic view of the light emitting diode package structure of FIG. 1.

FIG. 3 is a flow chart of a manufacturing method of a light emitting diode package structure according to one embodiment of the present disclosure.

FIGS. 4A, 4B, 4C, 4D, 4E, 4F, 4G and 4H respectively are cross-sectional schematic views of each of processing steps of the manufacturing method of the light emitting diode package structure.

### DETAILED DESCRIPTION

A number of examples of the present disclosure will be described below with reference to the accompanying drawings. The following description will include many practical details in order to be clear and specific. The reader, however, should understand that those practical details are not intended to be restrictive of the scope of the invention; in other words, the practical details are not essential to some embodiments of the invention.

Besides, for the sake of simplicity of the drawings, some conventional or commonly used structures and elements are drawn only schematically in the drawings, and repeated elements may be indicated by the same reference numeral or similar reference numerals.

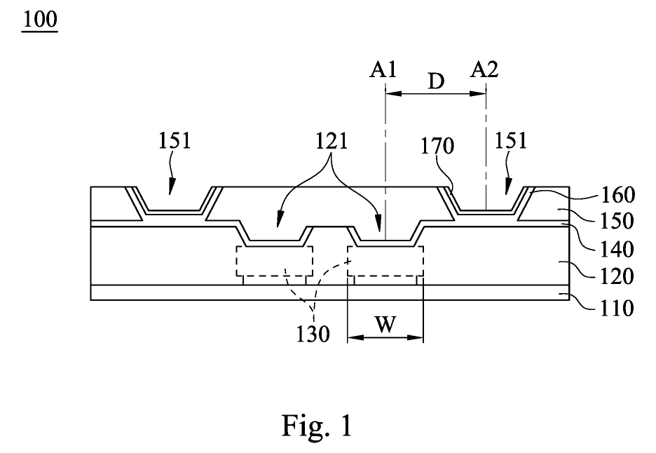

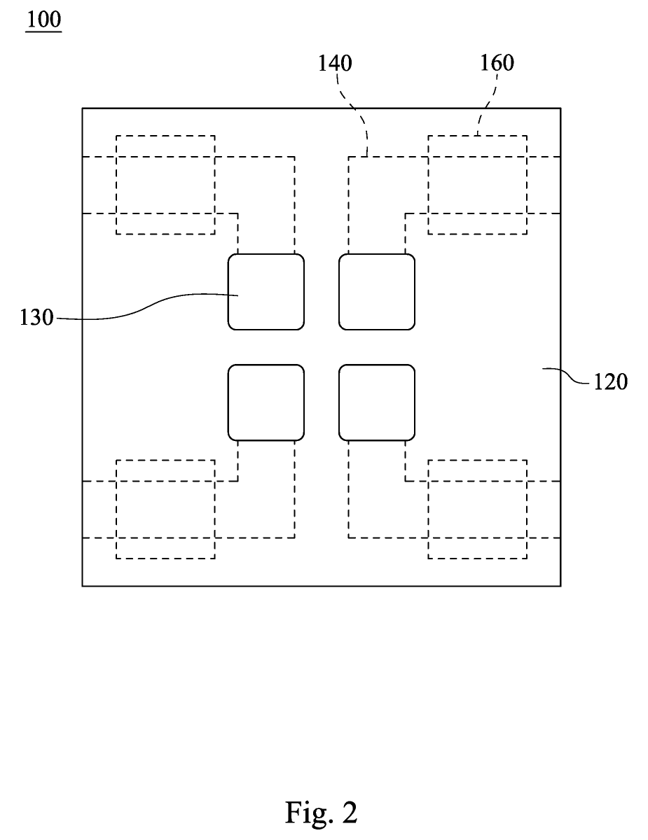

Please refer to FIGS. 1 and 2, FIG. 1 is a cross-sectional schematic view of a light emitting diode package structure 100 according to one embodiment of the present disclosure, FIG. 2 is a bottom schematic view of the light emitting diode package structure 100 of FIG. 1. The light emitting diode package structure 100 includes a conductive substrate 110, a first insulating layer 120, a plurality of light emitting diode elements 130, a first conductive layer 140, a second insulating layer 150 and a second conductive layer 160.

In detail, the conductive substrate 110 is a transparent conductive substrate. The first insulating layer 120 is disposed on a surface of the conductive substrate 110, and the first insulating layer 120 has a plurality of first through holes 121. The light emitting diode elements 130 are embedded in the first insulating layer 120, a light emitting surface of each of the light emitting diode elements 130 is connected to the conductive substrate 110, and a connecting surface of each of the light emitting diode elements 130 is exposed to each of the first through holes 121 which is corresponding to each of the light emitting diode elements 130. Therefore, the light emitting diode elements 130 can be electrically connected to other elements through the connecting surface where is exposed, it is favorable to improve the convenient of assembling, and the light emitting surface of the light emitting diode elements 130 faces toward the conductive substrate 110 to prevent the light emitting effect of the light emitting diode element 130 from being affected.

The first conductive layer 140 is connected between the first insulating layer 120 and the connecting surface of each of the light emitting diode elements 130, and the first insulating layer 120 is located between the first conductive layer 140 and the conductive substrate 110. The second insulating layer 150 is connected to the first conductive layer 140, and the first conductive layer 140 is located between the first insulating layer 120 and the second insulating layer 150. Therefore, the first conductive layer 140 can be electrically connected to the light emitting diode elements 130. Moreover, the first insulating layer 120 and the second insulating layer 150 can decrease interference of the first conductive layer 140 causing the outer circuit.

The second insulating layer 150 has a plurality of second through holes 151, and a part of the first conductive layer 140 is exposed to the second through holes 151. The second conductive layer 160 is disposed in the second through holes 151 and connected to the first conductive layer 140. Therefore, the first conductive layer 140 and the second conductive layer 160 can be electrically connected through the second through holes 151, which is favorable to improve the convenient of production.

The first insulating layer 120 has a first thickness, and the first thickness can be 1 μm to 50 μm. The second insulating layer 150 has a second thickness, and the second thickness is 1 μm to 50 μm. Thus, it can decrease the size of the light emitting diode package structure 100 and provide an effectively insulating ability at the same time.

Each of the first through holes 121 has a first central axis A1, each of the second through holes 151 has a second central axis A2, each of the light emitting diode elements 130 has a width W, and a distance D between the first central axis A1 and the second central axis A2 corresponding to the first central axis A1 is not greater than three times the width W. Therefore, by adjusting the distance D between each first through hole 121 and each second through hole 151, different product requirements can be satisfied.

As shown in FIG. 2, the first conductive layer 140 can extend outward from each of the light emitting diode elements 130 in a direction parallel to the conductive substrate 110, and the second conductive layer 160 can be formed on an extension path of the first conductive layer 140. In the other words, the light emitting diode package structure 100 of the present disclosure can adjust the shape and the position of the light emitting diode elements 130, the first conductive layer 140 and second conductive layer 160, thereby the present disclosure will not be limited by the structure shown in figures.

The light emitting diode package structure 100 can further include a protective layer 170, the protective layer 170 can be connected to the second conductive layer 160, and the second conductive layer 160 is located between the second insulating layer 150 and the protective layer 170. Therefore, the protective layer 170 can protect the second conductive layer 160 so as to decrease the loss of the second conductive layer 160.

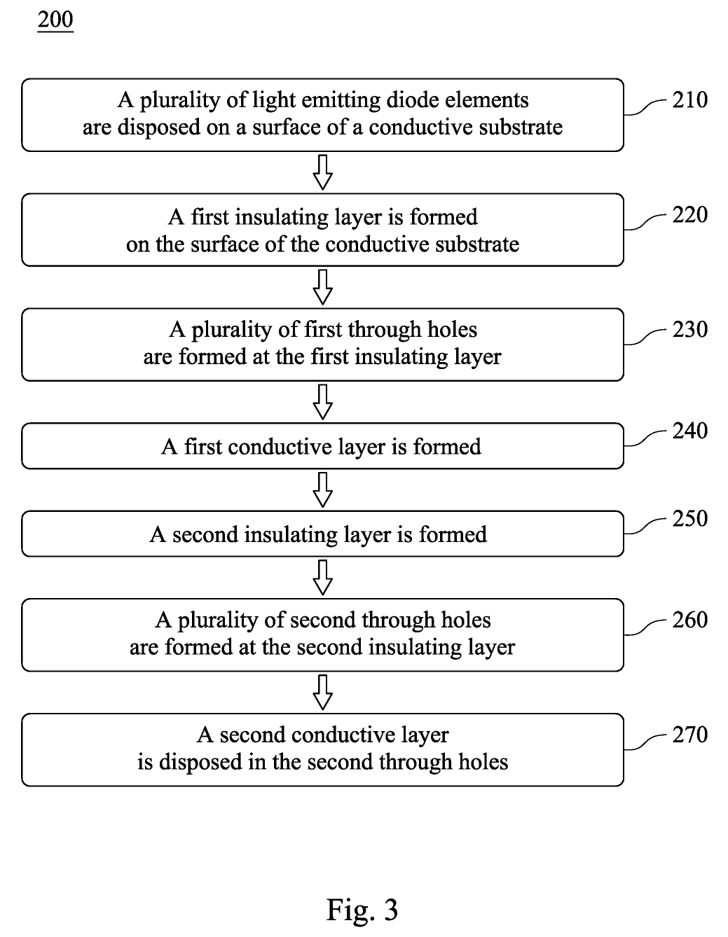

Please refer to FIG. 3, FIG. 3 is a flow chart of a manufacturing method of a light emitting diode package structure 200 according to one embodiment of the present disclosure. The manufacturing method of the light emitting diode package structure 200 includes step 210, step 220, step 230, step 240, step 250, step 260 and step 270.

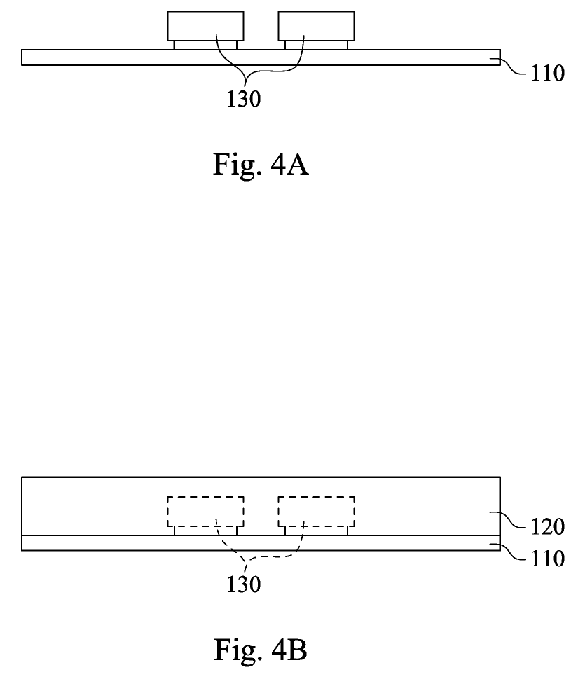

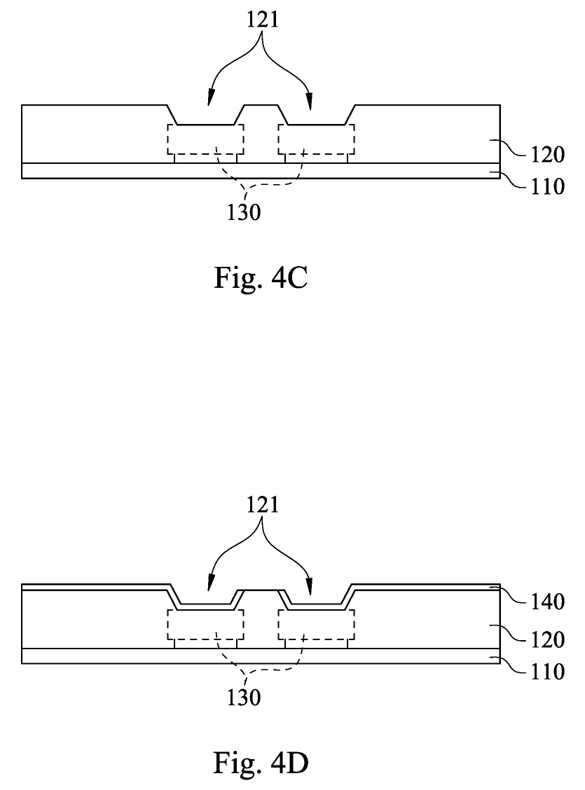

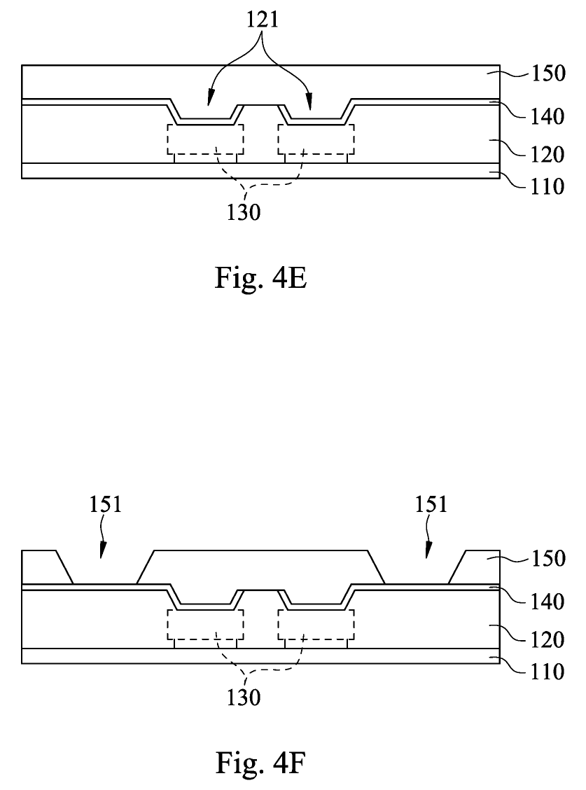

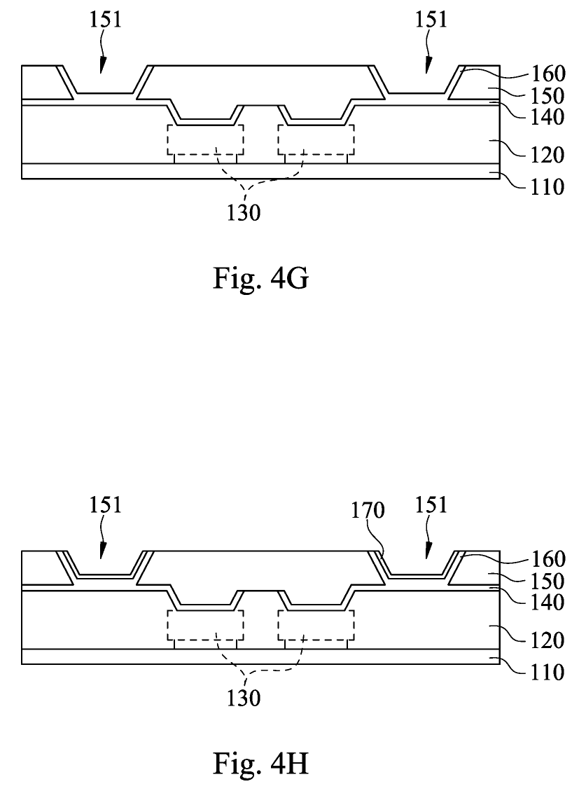

Please refer to FIGS. 4A, 4B, 4C, 4D, 4E, 4F, 4G and 4H. FIGS. 4A, 4B, 4C, 4D, 4E, 4F, 4G and 4H respectively are cross-sectional schematic views of each of processing steps of the manufacturing method of the light emitting diode package structure 200. In step 210, a plurality of light emitting diode elements 130 are disposed on a surface of a conductive substrate 110, and a light emitting surface of each of the light emitting diode elements 130 faces toward the conductive substrate 110. The conductive substrate 110 is a transparent conductive substrate. The connecting surface of the conductive substrate 110 and the light emitting diode elements 130 may have conductive structure to provide the circuit conduction of the light emitting diode elements 130.

In step 220, a first insulating layer 120 is formed on the surface of the conductive substrate 110, wherein the light emitting diode elements 130 are embedded in the first insulating layer 120. For example, after disposing the light emitting diode elements 130, it can be coated a layer of insulating material thereon, and then cured to form the first insulating layer 120, but the present disclosure is not limited by aforementioned process.

In step 230, a plurality of first through holes 121 are formed at the first insulating layer 120, and a connecting surface of each of the light emitting diode elements 130 is exposed to each of the first through holes 121 which is corresponding to each of the light emitting diode elements 130. The first through holes 121 can be formed via the photolithography process, and the first through holes 121 can approximately be a groove shape to facilitate subsequent deposition of materials in the first through holes 121.

In step 240, a first conductive layer 140 is formed, so that the first conductive layer 140 is connected to the first insulating layer 120 and the connecting surface of each of the light emitting diode elements130, and the first insulating layer 120 is located between the first conductive layer 140 and the conductive substrate 110. For example, the first conductive layer 140 can be formed via the sputtering process or chemical coating process, but the present disclosure is not limited by aforementioned process.

In step 250, a second insulating layer 150 is formed, so that the second insulating layer 150 is connected to the first conductive layer 140, and the first conductive layer 140 is located between the first insulating layer 120 and second insulating layer 150. For example, an insulating material can be coated on the first conductive layer 140, and then cured to form the second insulating layer 150, but the present disclosure is not limited by aforementioned process.

In step 260, a plurality of second through holes 151 is formed at the second insulating layer 150, so that a part of the first conductive layer 140 is exposed to the second through holes 151. The second through holes 151 can be formed via the photolithography process, and the second through holes 151 can approximately be a groove shape to facilitate subsequent deposition of materials in the second through holes 151.

In step 270, a second conductive layer 160 is disposed in the second through holes 151, and the second conductive layer 160 is connected to the first conductive layer 140 so as to obtain the light emitting diode package structure 100. For example, the second conductive layer 160 can be formed via the sputtering process or chemical coating process, but the present disclosure is not limited by aforementioned process.

It should be noted that conductive substrate 110, the structure or size of first insulating layer 120, light emitting diode elements 130, first conductive layer 140, second insulating layer 150 and second conductive layer 160 of the manufacturing method of the light emitting diode package structure 200 are the same or similar with the aforementioned light emitting diode package structure 100, and will not be described again herein.

Furthermore, the manufacturing method of the light emitting diode package structure 200 can further include a step, a protective layer 170 is formed. The protective layer 170 can be connected to the second conductive layer 160, so that the second conductive layer 160 is located between the second insulating layer 150 and the protective layer 170, thereby protecting the second insulating layer 150.

In summary, the light emitting diode package structure and the manufacturing method of the light emitting diode package structure of the present disclosure, by adopting transparent conductive substrate, and disposing the first through holes and the second through holes, thereby adjusting the position of the light emitting diode elements, the first conductive layer and the second conductive layer and light emitting direction of the light emitting diode elements, which is favorable to simplify process and improve the convenience during disposing structure, so that the light emitting diode package structure has a good light emitting effect, and when not displayed, the light emitting diode package structure of the present disclosure can still maintain good transparency.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light emitting diode package structure, comprising:
a conductive substrate;
a first insulating layer disposed on a surface of the conductive substrate, wherein the first insulating layer has a plurality of first through holes;
a plurality of light emitting diode elements embedded in the first insulating layer, wherein a light emitting surface of each of the light emitting diode elements is connected to the conductive substrate, and a connecting surface of each of the light emitting diode elements is exposed to each of the first through holes which is corresponding to each of the light emitting diode elements;
a first conductive layer connected between the first insulating layer and the connecting surface of each of the light emitting diode elements, wherein the first insulating layer is located between the first conductive layer and the conductive substrate;
a second insulating layer connected to the first conductive layer, wherein the first conductive layer is located between the first insulating layer and the second insulating layer, the second insulating layer has a plurality of second through holes, and a part of the first conductive layer is exposed to the second through holes; and
a second conductive layer disposed in the second through holes and connected to the first conductive layer;
wherein the conductive substrate is a transparent conductive substrate.

2. The light emitting diode package structure of claim 1, wherein the first insulating layer has a first thickness, wherein the first thickness is 1 μm to 50 μm.

3. The light emitting diode package structure of claim 1, wherein the second insulating layer has a second thickness, wherein the second thickness is 1 μm to 50 μm.

4. The light emitting diode package structure of claim 1, wherein each of the first through holes has a first central axis, each of the second through holes has a second central axis, each of the light emitting diode elements has a width, and a distance between the first central axis and the second central axis corresponding to the first central axis is not greater than three times the width.

5. The light emitting diode package structure of claim 1, further comprising a protective layer connected to the second conductive layer, wherein the second conductive layer is located between the second insulating layer and the protective layer.

6. The light emitting diode package structure of claim 1, wherein the first conductive layer extends outward from each of the light emitting diode elements in a direction parallel to the conductive substrate, and the second conductive layer is formed on an extension path of the first conductive layer.

7. The light emitting diode package structure of claim 1, wherein the second through holes are a groove shape.

8. A manufacturing method of a light emitting diode package structure, comprising:
disposing a plurality of light emitting diode elements on a surface of a conductive substrate, wherein a light emitting surface of each of the light emitting diode elements faces toward the conductive substrate;
forming a first insulating layer on the surface of the conductive substrate, wherein the light emitting diode elements are embedded in the first insulating layer;
forming a plurality of first through holes at the first insulating layer, wherein a connecting surface of each of the light emitting diode elements is exposed to each of the first through holes which is corresponding to each of the light emitting diode elements;
forming a first conductive layer, wherein the first conductive layer is connected to the first insulating layer and the connecting surface of each of the light emitting diode elements, and the first insulating layer is located between the first conductive layer and the conductive substrate;
forming a second insulating layer, wherein the second insulating layer is connected to the first conductive layer, and the first conductive layer is located between the first insulating layer and second insulating layer;
forming a plurality of second through holes at the second insulating layer, wherein a part of the first conductive layer is exposed to the second through holes; and
disposing a second conductive layer in the second through holes, wherein the second conductive layer is connected to the first conductive layer so as to obtain the light emitting diode package structure;
wherein, the conductive substrate is a transparent conductive substrate.

9. The manufacturing method of the light emitting diode package structure of claim 8, wherein the first insulating layer has a first thickness, the first thickness is 1 μm to 50 μm.

10. The manufacturing method of the light emitting diode package structure of claim 8, wherein the second insulating layer has a second thickness, the second thickness is 1 μm to 50 μm.

11. The manufacturing method of the light emitting diode package structure of claim 8, wherein each of the first through holes has a first central axis, each of the second through holes has a second central axis, each of the light emitting diode elements has a width, and a distance between the first central axis and the second central axis corresponding to the first central axis is not greater than three times the width.

12. The manufacturing method of the light emitting diode package structure of claim 8, further comprising:
a protective layer connected to the second conductive layer, wherein the second conductive layer is located between the second insulating layer and the protective layer.

13. The manufacturing method of the light emitting diode package structure of claim 8, wherein the first conductive layer extends outward from each of the light emitting diode elements in a direction parallel to the conductive substrate, and the second conductive layer is formed on an extension path of the first conductive layer.

14. The manufacturing method of the light emitting diode package structure of claim 8, wherein the second through holes are a groove shape.
